(19) United States
(12) Patent Application Publication
(10) Pub. No.: US 2026/0068736 A1
(43) Pub. Date: Mar. 5, 2026

(54) SEMICONDUCTOR PACKAGE

(71) Applicant: SAMSUNG ELECTRONICS CO., LTD., Suwon-si (KR)

(72) Inventor: Jinsu KIM, Suwon-si (KR)

(73) Assignee: SAMSUNG ELECTRONICS CO., LTD., Suwon-si (KR)

(21) Appl. No.: 19/225,608

(22) Filed: Jun. 2, 2025

(30) Foreign Application Priority Data
Aug. 30, 2024 (KR) 10-2024-0117887

(51) Int. Cl. H01L 23/31; H01L 23/48; H01L 23/498; H01L 23/544

(52) U.S. Cl. CPC H01L 23/3107

(57) ABSTRACT

A semiconductor package may include: a lower insulating layer including recess grooves recessed into the lower insulating layer from a top surface of the lower insulating layer; a first semiconductor chip on the lower insulating layer in a first vertical direction, and spaced apart from the recess grooves in at least one horizontal direction, the first semiconductor chip including a first through electrode; a second semiconductor chip on the first semiconductor chip in the first vertical direction; and a molding layer in contact with the top surface of the lower insulating layer, a side surface of the first semiconductor chip, and a side surface of the second semiconductor chip, wherein, in a plan view of the semiconductor package, a size of an area of the lower insulating layer is greater than a size of an area of the first semiconductor chip, and wherein portions of the molding layer are in the recess grooves of the lower insulating layer.

### CROSS-REFERENCE TO RELATED APPLICATION

This application is based on and claims priority under 35 U.S.C. § 119 to Korean Patent Application No. 10-2024-0117887, filed on Aug. 30, 2024, in the Korean Intellectual Property Office, the disclosure of which is incorporated by reference herein in its entirety.

### BACKGROUND

The present disclosure relates to a semiconductor package, and more particularly, to a semiconductor package in which a plurality of semiconductor chips are stacked.

With the recent development of electronic industries and needs of users, electronic devices have become more compact, multifunctional, and large, and thus highly integrated semiconductor chips are required. Therefore, there is a need for a semiconductor package, which includes a highly integrated semiconductor chip with an increased number of connection terminals for input/output (I/O) while securing connection reliability.

### SUMMARY

According to one or more embodiments, a semiconductor package in which a delamination phenomenon of a molding layer may be suppressed may be provided.

Embodiments of the disclosure are not limited to the above-mentioned aspect, and other aspects of embodiments of the disclosure not mentioned may be clearly understood by those of ordinary skill in the art from the following description.

According to an aspect of the disclosure, a semiconductor package includes: a lower insulating layer including recess grooves recessed into the lower insulating layer from a top surface of the lower insulating layer; a first semiconductor chip on the lower insulating layer in a first vertical direction, and spaced apart from the recess grooves in at least one horizontal direction, the first semiconductor chip including a first through electrode; a second semiconductor chip on the first semiconductor chip in the first vertical direction; and a molding layer in contact with the top surface of the lower insulating layer, a side surface of the first semiconductor chip, and a side surface of the second semiconductor chip, wherein, in a plan view of the semiconductor package, a size of an area of the lower insulating layer is greater than a size of an area of the first semiconductor chip, and wherein portions of the molding layer are in the recess grooves of the lower insulating layer.

According to an aspect of the disclosure, a semiconductor package includes: a lower insulating layer including recess grooves recessed into the lower insulating layer from a top surface of the lower insulating layer, and alignment grooves spaced apart from the recess grooves; a first semiconductor chip on the lower insulating layer in a first vertical direction, and spaced apart from the recess grooves and the alignment grooves in at least one horizontal direction, the first semiconductor chip including a first through electrode; a plurality of second semiconductor chips on the first semiconductor chip in the first vertical direction; and a molding layer in contact with the top surface of the lower insulating layer, a side surface of the first semiconductor chip, and side surfaces of the plurality of second semiconductor chips, wherein side surfaces of the first semiconductor chip overlap the top surface of the lower insulating layer in the first vertical direction, the molding layer includes protrusions in contact with a side surface of each of the recess grooves of the lower insulating layer or in contact with a side surface of each of the alignment grooves of the lower insulating layer, and a shape of each of the recess grooves is different from a shape of each of the alignment grooves.

According to an aspect of the disclosure, a semiconductor package includes: a lower insulating layer including recess grooves recessed into the lower insulating layer from a top surface of the lower insulating layer, and alignment grooves spaced apart from the recess grooves; a first semiconductor chip on the lower insulating layer in a first vertical direction, and spaced apart from the recess grooves and the alignment grooves in at least one horizontal direction, the first semiconductor chip including a first through electrode; a conductive pillar that penetrates the lower insulating layer and is electrically connected to the first semiconductor chip; an external connection terminal connected to the conductive pillar; a plurality of second semiconductor chips on the first semiconductor chip; and a molding layer in contact with the top surface of the lower insulating layer, a side surface of the first semiconductor chip, and side surfaces of the plurality of second semiconductor chips, wherein side surfaces of the first semiconductor chip overlap the top surface of the lower insulating layer in the first vertical direction, wherein side surfaces of each of the plurality of second semiconductor chips overlap a top surface of the first semiconductor chip in the first vertical direction, the molding layer includes protrusions in contact with a side surface of each of the recess grooves of the lower insulating layer or in contact with a side surface of each of the alignment grooves of the lower insulating layer, wherein an outer surface of the molding layer is coplanar with an outer surface of the lower insulating layer, and the first semiconductor chip is inside the molding layer, and wherein a shape of each of the recess grooves is different from a shape of each of the alignment grooves.

### BRIEF DESCRIPTION OF THE DRAWINGS

The above and/or other aspects will be more clearly understood from the following detailed description taken in conjunction with the accompanying drawings, in which:

FIG. 1 is a bottom view schematically illustrating a semiconductor package according to one or more embodiments;

FIG. 2 is a cross-sectional view schematically illustrating the semiconductor package of FIG. 1 taken along a line A1-A1′ of FIG. 1;

FIG. 3 is an enlarged view schematically illustrating a portion EX1 of FIG. 2 in the semiconductor package of FIG. 2;

FIG. 4 is an enlarged view schematically illustrating a partially enlarged portion of the semiconductor package according to one or more embodiments;

FIG. 5 is a cross-sectional view schematically illustrating a semiconductor package according to one or more embodiments;

FIG. 6 is a bottom view schematically illustrating a semiconductor package according to one or more embodiments;

FIG. 7 is a cross-sectional view schematically illustrating a semiconductor package of FIG. 6 taken along a line A2-A2′ of FIG. 6;

FIG. 8 is a bottom view schematically illustrating a semiconductor package according to one or more embodiments;

FIG. 9 is a cross-sectional view schematically illustrating a semiconductor package of FIG. 8 taken along a line A3-A3′ of FIG. 8;

FIG. 10 is a bottom view schematically illustrating a semiconductor package according to one or more embodiments;

FIG. 11 is a bottom view schematically illustrating a semiconductor package according to one or more embodiments; and

FIGS. 12A to 12K are schematic diagrams illustrating a method of manufacturing a semiconductor package according to one or more embodiments.

### DETAILED DESCRIPTION

Since embodiments of the disclosure may undergo various changes and have various forms, some non-limiting example embodiments will be illustrated in the drawings and described in detail. However, this is not intended to limit the embodiments of the disclosure to a specific form.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

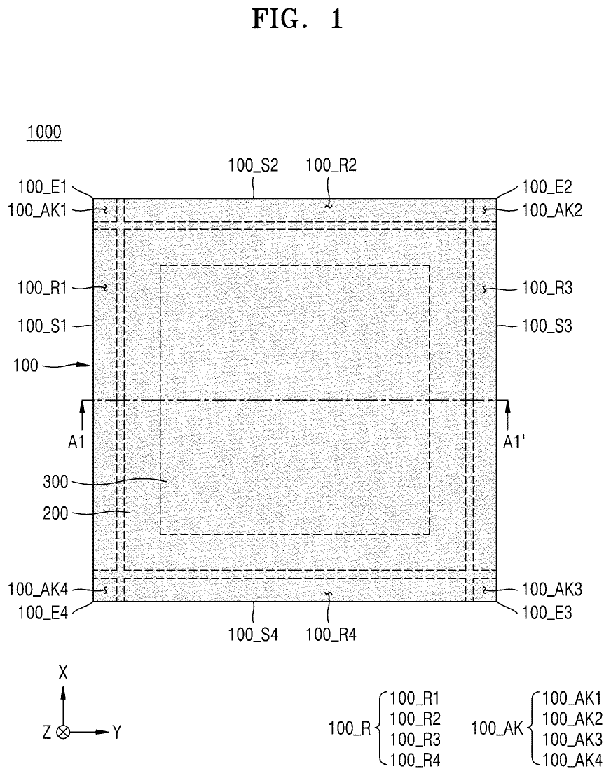

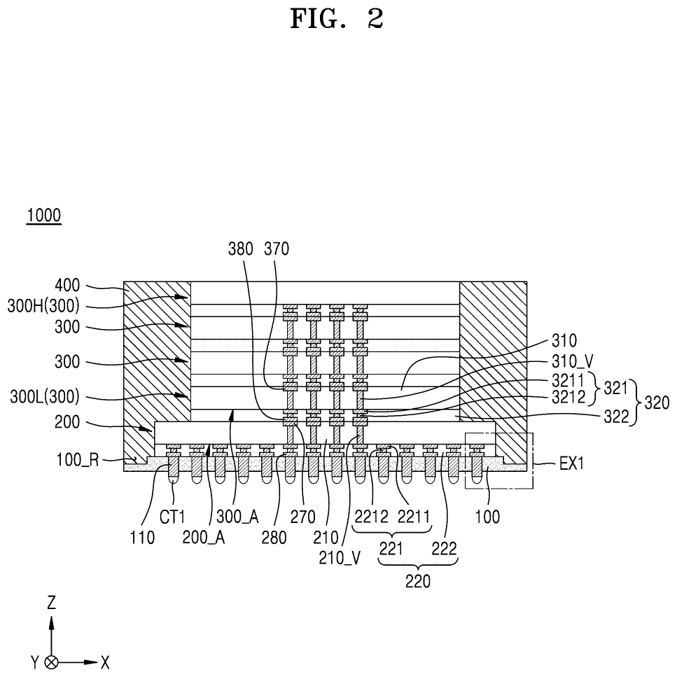

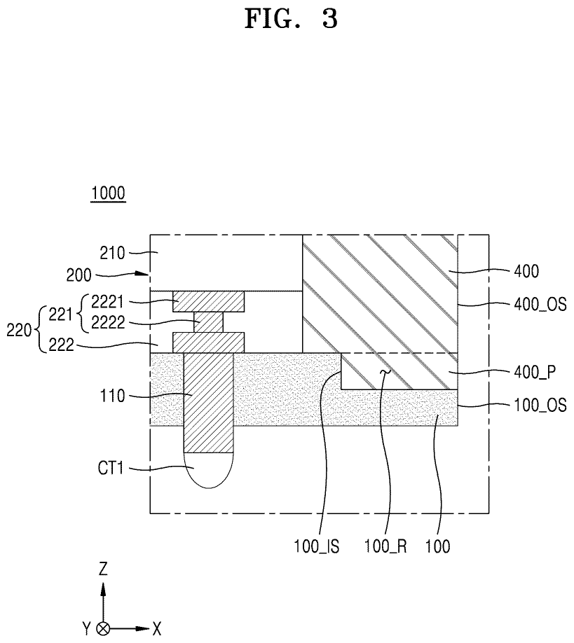

FIG. 1 is a bottom view schematically illustrating a semiconductor package 1000 according to one or more embodiments. FIG. 2 is a cross-sectional view schematically illustrating the semiconductor package 1000 of FIG. 1 taken along a line A1-A1′ of FIG. 1. FIG. 3 is an enlarged view schematically illustrating a portion EX1 of FIG. 2 in the semiconductor package 1000 of FIG. 2.

Referring to FIGS. 1 to 3, the semiconductor package 1000 may include a lower insulating layer 100, a first semiconductor chip 200, a second semiconductor chip 300, and a molding layer 400. In FIG. 2, four second semiconductor chips 300 are stacked on the first semiconductor chip 200, but the number of second semiconductor chips 300 stacked on the first semiconductor chip 200 is not limited thereto.

Hereinafter, unless otherwise defined, a direction parallel to a bottom surface of the lower insulating layer 100 may be defined as a first horizontal direction (X-direction), a direction perpendicular to the bottom surface of the lower insulating layer 100 may be defined as a vertical direction (Z-direction), and a direction perpendicular to the first horizontal direction (X-direction) and the vertical direction (Z-direction) may be defined as a second horizontal direction (Y-direction). Herein, a “horizontal direction” may be defined as the first horizontal direction (X-direction) and/or the second horizontal direction (Y-direction).

The lower insulating layer 100 may be positioned under the first semiconductor chip 200 and may protect a plurality of first lower pads 280 of the first semiconductor chip 200 from the outside. The lower insulating layer 100 may be divided into a central region and an edge region. The edge region of the lower insulating layer 100 may surround the central region of the lower insulating layer 100. For example, a center of a top surface of the lower insulating layer 100 may be located in the central region of the lower insulating layer 100, and outer surfaces 100_OS of the lower insulating layer 100 may be located in the edge region of the lower insulating layer 100.

The outer surfaces 100_OS of the lower insulating layer 100 may include a first side surface 100_S1, a second side surface 100_S2, a third side surface 100_S3, and a fourth side surface 100_S4. The third side surface 100_S3 of the lower insulating layer 100 may be opposite to the first side surface 100_S1 of the lower insulating layer 100. The second side surface 100_S2 of the lower insulating layer 100 may be adjacent to the first side surface 100_S1 of the lower insulating layer 100. The fourth side surface 100_S4 of the lower insulating layer 100 may be opposite to the second side surface 100_S2 of the lower insulating layer 100.

The top surface of the lower insulating layer 100 may include a first vertex 100_E1, a second vertex 100_E2, a third vertex 100_E3, and a fourth vertex 100_E4. The first vertex 100_E1 may be located on an edge of the lower insulating layer 100 where the first side surface 100_S1 of the lower insulating layer 100 and the second side surface 100_S2 of the lower insulating layer 100 are in contact with each other. The second vertex 100_E2 may be located on an edge of the lower insulating layer 100 where the second side surface 100_S2 of the lower insulating layer 100 and the third side surface 100_S3 of the lower insulating layer 100 are in contact with each other. The third vertex 100_E3 may be located on an edge of the lower insulating layer 100 where the third side surface 100_S3 of the lower insulating layer 100 and the fourth side surface 100_S4 of the lower insulating layer 100 are in contact with each other. The fourth vertex 100_E4 may be located on an edge of the lower insulating layer 100 where the fourth side surface 100_S4 of the lower insulating layer 100 and the first side surface 100_S1 of the lower insulating layer 100 are in contact with each other.

An area of the lower insulating layer 100 may be larger than an area of the first semiconductor chip 200. For example, the side surfaces of the first semiconductor chip 200 may overlap the top surface of the lower insulating layer 100 in the vertical direction (Z direction). The first semiconductor chip 200 may be located on an upper-middle region of the lower insulating layer 100.

The lower insulating layer 100 may include recess grooves 100_R. Each of the recess grooves 100_R may be at least partially recessed from the top surface of the lower insulating layer 100 into the inside of the lower insulating layer 100. For example, the recess grooves 100_R may not completely penetrate the lower insulating layer 100. For example, the recess grooves 100_R may be located at an edge region of the lower insulating layer 100. The recess grooves 100_R may be spaced apart from the first semiconductor chip 200 in a horizontal direction.

In one or more embodiments, as illustrated in FIG. 2, each of the recess grooves 100_R may be recessed inward from the outer surfaces 100_OS of the lower insulating layer 100. That is, the recess grooves 100_R may overlap the outer surfaces 100_OS of the lower insulating layer 100 in the vertical direction (Z direction). However, unlike the illustration in FIG. 2, the recess grooves 100_R may be spaced apart from the outer surfaces 100_OS of the lower insulating layer 100. In one or more embodiments, when the recess grooves 100_R overlap the outer surfaces 100_OS of the lower insulating layer 100 in the vertical direction (Z direction), the recess grooves 100_R may be referred to as chamfers.

In one or more embodiments, each of the recess grooves 100_R may extend along sides of the top surface of the lower insulating layer 100. For example, the recess grooves 100_R may include a first recess groove 100_R1, a second recess groove 100_R2, a third recess groove 100_R3, and a fourth recess groove 100_R4. The first recess groove 100_R1 may overlap with the first side surface 100_S1 of the lower insulating layer 100 in the vertical direction (Z direction), and may extend along the first side surface 100_S1 of the lower insulating layer 100. The second recess groove 100_R2 may overlap with the second side surface 100_S2 of the lower insulating layer 100 in the vertical direction (Z direction), and may extend along the second side surface 100_S2 of the lower insulating layer 100. The third recess groove 100_R3 may overlap with the third side surface 100_S3 of the lower insulating layer 100 in the vertical direction (Z direction), and may extend along the third side surface 100_S3 of the lower insulating layer 100. The fourth recess groove 100_R4 may overlap with the fourth side surface 100_S4 of the lower insulating layer 100 in the vertical direction (Z direction), and may extend along the fourth side surface 100_S4 of the lower insulating layer 100. In one or more embodiments, the first recess groove 100_R1, the second recess groove 100_R2, the third recess groove 100_R3, and the fourth recess groove 100_R4 may meet and communicate with the adjacent recess grooves at vertices of the top surface of the lower insulating layer 100.

The lower insulating layer 100 may further include alignment grooves 100_AK. Each of the alignment grooves 100_AK may be partially recessed inward from the top surface of the lower insulating layer 100. In one or more embodiments, a depth of each of the alignment grooves 100_AK may be independent of a depth of each of the recess grooves 100_R. For example, a depth of each of the alignment grooves 100_AK may be different from a depth of each of the recess grooves 100_R.

A shape of each of the alignment grooves 100_AK may be different from a shape of each of the recess grooves 100_R. For example, the alignment grooves 100_AK may be used when adjusting the position of the first semiconductor chip 200 in a semiconductor package manufacturing process. In the alignment process of the first semiconductor chip 200, shapes of the alignment grooves 100_AK and the recess grooves 100_R may be different from each other to prevent confusion between the alignment grooves 100_AK and the recess grooves 100_R.

In one or more embodiments, the shape of each of the alignment grooves 100_AK may be square, and the shape of each of the recess grooves 100_R may be rectangular. A width of each of the alignment grooves 100_AK may be different from a width of each of the recess grooves 100_R. In one or more embodiments, an area of each of the alignment grooves 100_AK may be different from an area of each of the recess grooves 100_R.

In one or more embodiments, the alignment grooves 100_AK may be located at an edge region of the lower insulating layer 100. For example, the alignment grooves 100_AK may be located on vertices of the top surface of the lower insulating layer 100. For example, the alignment grooves 100_AK may be spaced apart from the first semiconductor chip 200 in a horizontal direction.

The alignment grooves 100_AK may include a first alignment groove 100_AK1, a second alignment groove 100_AK2, a third alignment groove 100_AK3, and a fourth alignment groove 100_AK4. The first alignment groove 100_AK1 may be located on a first vertex 100_E1 of the top surface of the lower insulating layer 100. The second alignment groove 100_AK2 may be located on a second vertex 100_E2 of the top surface of the lower insulating layer 100. The third alignment groove 100_AK3 may be located on a third vertex 100_E3 of the top surface of the lower insulating layer 100. The fourth alignment groove 100_AK4 may be located on a fourth vertex 100_E4 of the top surface of the lower insulating layer 100.

The alignment grooves 100_AK may be spaced apart from the recess grooves 100_R. For example, the alignment grooves 100_AK and the recess grooves 100_R may be spaced apart from each other in the horizontal direction to separate the alignment grooves 100_AK and the recess grooves 100_R from each other. For example, the first recess groove 100_R1 may be positioned between the first alignment groove 100_AK1 and the fourth alignment groove 100_AK4. The second recess groove 100_R2 may be positioned between the second alignment groove 100_AK2 and the first alignment groove 100_AK1. The third recess groove 100_R3 may be positioned between the third alignment groove 100_AK3 and the second alignment groove 100_AK2. The fourth recess groove 100_R4 may be positioned between the fourth alignment groove 100_AK4 and the third alignment groove 100_AK3.

In one or more embodiments, the lower insulating layer 100 may include photoresistive polyimide (PSPI). In one or more embodiments, the lower insulating layer 100 may include an oxide such as, for example, silicon oxide.

In one or more embodiments, the semiconductor package 1000 may further include conductive pillars 110. Each of the conductive pillars 110 may extend from the top surface of the lower insulating layer 100 to the bottom surface of the lower insulating layer 100. For example, each of the conductive pillars 110 may penetrate the lower insulating layer 100. The conductive pillars 110 may be electrically connected to the first semiconductor chip 200. For example, the conductive pillars 110 may be connected to a plurality of first lower pads 280 of the first semiconductor chip 200, respectively.

In one or more embodiments, the conductive pillars 110 may be spaced apart from the recess grooves 100_R and alignment grooves 100_AK of the lower insulating layer 100 in the horizontal direction. For example, the conductive pillars 110 may be located below the first semiconductor chip 200. The conductive pillars 110 may be located in a central region of the lower insulating layer 100. For example, the conductive pillars 110 may not be located at an edge region of the lower insulating layer 100.

External connection terminals CT1 may be attached to the conductive pillars 110, respectively. The external connection terminals CT1 may be configured to electrically and physically connect the semiconductor package 1000 with an external device on which the semiconductor package 1000 is mounted. The external connection terminals CT1 may include, for example, solder balls or solder bumps.

In one or more embodiments, an under bump metallization (UBM) layer may be positioned between the conductive pillars 110 and the plurality of first lower pads 280 of the first semiconductor chip 200 to facilitate adhesion between the conductive pillars 110 and the plurality of first lower pads 280 of the first semiconductor chip 200.

In one or more embodiments, the lower insulating layer 100 may have a single layer structure. For example, a patterned redistribution structure may not be located inside the lower insulating layer 100. In some configurations, the thickness of the lower insulating layer 100 may be 3 μm to 7 μm. In this case, the lower insulating layer 100 may be referred to as a passivation layer.

In one or more embodiments, a horizontal width of each of the conductive pillars 110 may decrease toward the first semiconductor chip 200. For example, a horizontal width of each of the conductive pillars 110 may decrease toward the top surface of the lower insulating layer 100. For example, the conductive pillars 110 may be referred to as a plurality of through vias. In one or more embodiments, each of the conductive pillars 110 may include a metal material such as, for example, aluminum, copper, or tungsten.

In one or more embodiments, each of the conductive pillars 110 may protrude to the outside of the lower insulating layer 100. For example, each of the conductive pillars 110 may include a portion protruding downward from the bottom surface of the lower insulating layer 100. For example, a bottom surface of each of the conductive pillars 110 and the bottom surface of the lower insulating layer 100 may not be located on the same plane as each other.

The first semiconductor chip 200 may be positioned above the lower insulating layer 100. For example, the side surfaces of the first semiconductor chip 200 may be located above the top surface of the lower insulating layer 100.

The first semiconductor chip 200 may include a first substrate 210 having an active surface 200_A and an inactive surface, which are opposite to each other, a first wiring structure 220 formed on the active surface 200_A of the first substrate 210, and a plurality of first through electrodes 210_V connected to the first wiring structure 220 and penetrating at least a portion of the first substrate 210 of the first semiconductor chip 200.

The first substrate 210 may include, for example, a semiconductor material such as silicon (Si). Alternatively, the first substrate 210 may include a semiconductor material such as germanium (Ge).

A semiconductor device including a plurality of individual devices of various types may be formed on the active surface 200_A of the first substrate 210. The plurality of individual devices of the first semiconductor chip 200 may include image sensors such as various microelectronic devices such as, for example, metal-oxide-semiconductor field effect transistors (MOSFET) (e.g., a complementary metal-insulator-semiconductor (CMOS) transistor), system large scale integration (LSI), and CMOS imaging sensors (CIS), micro-electro-mechanical systems (MEMS), active devices, passive devices, etc.

Side surfaces of the first wiring structure 220 may be aligned (e.g., coplanar) with the side surfaces of the first substrate 210 in the vertical direction (Z direction). The first wiring structure 220 may include a first wiring pattern 221 and a first wiring insulating layer 222 surrounding the first wiring pattern 221. The first wiring pattern 221 may include a first wiring line 2211 extending in the horizontal direction and a first wiring via 2212 extending in the vertical direction (Z direction) from the first wiring line 2211. The first wiring pattern 221 may be electrically connected to the plurality of individual devices of the first semiconductor chip 200.

The first semiconductor chip 200 may be arranged such that the active surface 200_A of the first substrate 210 faces downward in the vertical direction (Z direction), and the inactive surface thereof faces upward in the vertical direction (Z direction). For example, the first semiconductor chip 200 may be positioned on the lower insulating layer 100 such that the active surface 200_A of the first substrate 210 faces the lower insulating layer 100. Unless otherwise stated in the present specification, a rear surface of the first semiconductor chip 200 refers to a side thereof that faces in a same direction as a facing direction of the inactive surface of the first substrate 210, and a front surface of the first semiconductor chip 200 refers to a side thereof that faces in a same direction as a facing direction of the active surface 200_A of the first substrate 210.

The first semiconductor chip 200 may include a plurality of first lower pads 280 and a plurality of first upper pads 270. The plurality of first lower pads 280 may be positioned at (e.g., in or on) the bottom surface of the first semiconductor chip 200, and the plurality of first upper pads 270 may be positioned at (e.g., in or on) the top surface of the first semiconductor chip 200. The plurality of first lower pads 280 may be a portion of the first wiring structure 220. For example, the plurality of first lower pads 280 may be a portion of the first wiring pattern 221 of the first wiring structure 220. The plurality of first upper pads 270 may be electrically connected to the plurality of first lower pads 280 through the plurality of first through electrodes 210_V. In one or more embodiments, the plurality of first upper pads 270 may be integrally formed with the plurality of first through electrodes 210_V.

For example, the conductive pillars 110 may be in direct contact with the plurality of first lower pads 280 of the first semiconductor chip 200. The conductive pillars 110 may be positioned on the bottom surfaces of the plurality of first lower pads 280, respectively. For example, the conductive pillars 110 may respectively overlap with the plurality of first lower pads 280 of the first semiconductor chip 200 in the vertical direction (Z direction). For example, the external connection terminals CT1 attached to the conductive pillars 110 may also be positioned below the first semiconductor chip 200.

The plurality of second semiconductor chips 300 may be positioned above the first semiconductor chip 200. The plurality of second semiconductor chips 300 may be stacked on each other in the vertical direction (Z direction). In one or more embodiments, the semiconductor package 1000 may include only one second semiconductor chip 300. The plurality of second semiconductor chips 300 may be positioned on a central region of the lower insulating layer 100.

Each of the plurality of second semiconductor chips 300 may include a second substrate 310 having an active surface 300_A and an inactive surface, which are opposite to each other, and a second wiring structure 320 formed on the active surface 300_A of the second substrate 310.

Each of the plurality of second semiconductor chips 300 other than the uppermost second semiconductor chip 300H may further include a plurality of second through electrodes 310_V connected to the second wiring structure 320 and penetrating at least a portion of the second substrate 310. The uppermost second semiconductor chip 300H positioned at the uppermost end among the plurality of second semiconductor chips 300 may not include a plurality of second through electrodes 310_V. However, embodiments are not limited thereto, and the uppermost second semiconductor chip 300H may also include a plurality of second through electrodes 310_V.

The second substrate 310 may include, for example, a semiconductor material such as silicon (Si). Alternatively, the second substrate 310 may include a semiconductor material such as germanium (Ge).

A semiconductor device including a plurality of individual devices of various types may be formed on the active surface 300_A of the second substrate 310. The plurality of individual devices of each of the plurality of second semiconductor chips 300 may include memory cells. For example, each of the memory cells may be a non-volatile memory cell such as flash memory, phase-change random access memory (PRAM), magnetoresistive random access memory (MRAM), ferroelectric random access memory (FeRAM), or resistive random access memory (RRAM). In one or more embodiments, the memory cell may be a volatile memory cell such as a dynamic random access memory (DRAM) or a static random access memory (SRAM).

The second wiring structure 320 may include a second wiring pattern 321 and a second wiring insulating layer 322 surrounding the second wiring pattern 321. The second wiring pattern 321 may include a second wiring line 3211 extending in the horizontal direction and a second wiring via 3212 extending from the second wiring line 3211 in the vertical direction (Z direction). The second wiring structure 320 of each of the plurality of second semiconductor chips 300 may be electrically connected to the plurality of individual devices of each of the plurality of second semiconductor chips 300.

Each of the plurality of second semiconductor chips 300 may be sequentially stacked on the first semiconductor chip 200 in the vertical direction (Z direction) such that the active surface 300_A of the second substrate 310 faces downward in the vertical direction (Z direction). For example, each of the plurality of second semiconductor chips 300 may be stacked on the first semiconductor chip 200 such that the active surface 300_A of the second substrate 310 faces the first semiconductor chip 200. Unless otherwise stated in the present specification, a rear surface of each of the plurality of second semiconductor chips 300 refers to a side thereof that faces in a same direction as a facing direction of an inactive surface of the second substrate 310, and a front surface of each of the plurality of second semiconductor chips 300 refers to a side thereof that faces in a same direction as a facing direction of the active surface 300_A of the second substrate 310.

Each of the plurality of second semiconductor chips 300 may include a plurality of second lower pads 380 and a plurality of second upper pads 370. The plurality of second lower pads 380 may be positioned at (e.g., in or on) the bottom surfaces of the plurality of second semiconductor chips 300, respectively, and may be a portion of the second wiring structure 320. The plurality of second upper pads 370 may be positioned at (e.g., in or on) top surfaces of the plurality of second semiconductor chips 300, respectively, and may be electrically connected to the plurality of second lower pads 380 through a plurality of second through electrodes 310_V and the second wiring pattern 321, respectively. In one or more embodiments, the plurality of second upper pads 370 may be integrally formed with the plurality of second through electrodes 310_V. In one or more embodiments, the uppermost second semiconductor chip 300H may not have the plurality of second through electrodes 310_V and the plurality of second upper pads 370.

In one or more embodiments, a thickness (e.g., a length in the vertical direction (Z direction)) of each of the plurality of second semiconductor chips 300 may be, for example, 20 μm to 80 μm. The thickness of each of the plurality of second semiconductor chips 300 may be substantially the same as each other. In one or more embodiments, the uppermost second semiconductor chip 300H may be thicker than other ones from among the second semiconductor chips 300.

In one or more embodiments, the widths (e.g., the lengths in the horizontal direction) of the plurality of second semiconductor chips 300 may be substantially the same as each other. Side surfaces of the plurality of second semiconductor chips 300 may be aligned (e.g., coplanar) with each other in the vertical direction (Z direction).

In one or more embodiments, an area of a bottom surface of each of the plurality of second semiconductor chips 300 may be smaller than an area of the top surface of the first semiconductor chip 200. For example, a width of each of the plurality of second semiconductor chips 300 may be less than a width of the first semiconductor chip 200. For example, side surfaces of the plurality of second semiconductor chips 300 may overlap the top surface of the first semiconductor chip 200 in the vertical direction (Z direction).

In one or more embodiments, the first semiconductor chip 200 may include a serial-parallel conversion circuit and may be a buffer chip for controlling the plurality of second semiconductor chips 300, and each of the plurality of second semiconductor chips 300 may be a memory chip including memory cells. For example, the semiconductor package 1000 including the first semiconductor chip 200 and the plurality of second semiconductor chips 300 may be a high bandwidth memory (HBM), the first semiconductor chip 200 may be an HBM controller die, and each of the plurality of second semiconductor chips 300 may be a dynamic random access memory (DRAM) die.

In one or more embodiments, the lowermost second semiconductor chip 300L, located at the lowermost end among the plurality of second semiconductor chips 300, and the first semiconductor chip 200 may be coupled through a hybrid bonding. For example, the plurality of second lower pads 380 of the lowermost second semiconductor chip 300L may be diffusely bonded by heat to the plurality of first upper pads 270 of the first semiconductor chip 200 so as to be a single body.

For example, while the plurality of second lower pads 380 of the lowermost second semiconductor chip 300L and the plurality of first upper pads 270 of the first semiconductor chip 200 are diffusely bonded, the second wiring insulating layer 322 surrounding the plurality of second lower pads 380 of the lowermost second semiconductor chip 300L may be diffusely bonded to the insulating layer surrounding the plurality of first upper pads 270 of the first semiconductor chip 200 so as to be a single body.

In one or more embodiments, an area of the top surface of the insulating layer surrounding the plurality of first upper pads 270 of the first semiconductor chip 200 may be a same size as an area of the top surface of the first semiconductor chip 200, and a portion of the top surface of the insulating layer surrounding the plurality of first upper pads 270 of the first semiconductor chip 200 may be in contact with the molding layer 400.

In one or more embodiments, adjacent ones of the second semiconductor chips 300 among the plurality of second semiconductor chips 300 may be coupled to each other through hybrid bonding. For convenience of description, description will be made based on two adjacent ones of the second semiconductor chips 300. Among the two second semiconductor chips 300, the plurality of second upper pads 370 of the lower one of the second semiconductor chips 300 and the plurality of second lower pads 380 of the upper one of the second semiconductor chips 300 may be diffusely bonded by heat to be a single body. At the same time, an insulating layer surrounding the plurality of second upper pads 370 of the lower one of the second semiconductor chips 300 and an insulating layer surrounding the plurality of second lower pads 380 of the upper one of the second semiconductor chips 300 may be diffusely bonded by heat to be a single body.

However, the bonding method between the lowermost second semiconductor chip 300L and the first semiconductor chip 200 and the bonding method between the plurality of second semiconductor chips 300 are not limited thereto, and the lowermost second semiconductor chip 300L, the first semiconductor chip 200, and the plurality of second semiconductor chips 300 may be bonded to each other by connection terminals (e.g., solder balls), an adhesive film (e.g., an anisotropic conductive film (ACF)), or a direct bonding method.

The molding layer 400 may be positioned on the lower insulating layer 100 and may be in contact with side surfaces of each of the first semiconductor chip 200 and the second semiconductor chips 300. For example, the molding layer 400 may be in contact with the top surface of the lower insulating layer 100. A portion of the molding layer 400 may be located in the recess grooves 100_R of the lower insulating layer 100. In one or more embodiments, a portion of the molding layer 400 may be located inside the alignment grooves 100_AK of the lower insulating layer 100. For example, a portion of the molding layer 400 may be in contact with the bottom surface and the inner surface 100_IS of each of the recess grooves 100_R of the lower insulating layer 100.

In one or more embodiments, the molding layer 400 may further include protrusions 400_P. The protrusions 400_P of the molding layer 400 may protrude downward from the bottom surface of the molding layer 400 and may be located in the recess grooves 100_R or alignment grooves 100_AK of the lower insulating layer 100. For example, the protrusions 400_P may be positioned on an edge region of the lower insulating layer 100.

For example, each of the protrusions 400_P of the molding layer 400 may be in contact with a portion that defines recess grooves 100_R or a portion that defines alignment grooves 100_AK, on the top surface of the lower insulating layer 100. For example, the molding layer 400 may completely cover the side surfaces of the second semiconductor chip 300, the side surfaces of the first semiconductor chip 200, and the inner surfaces 100_IS of the recess grooves 100_R of the lower insulating layer 100.

In one or more embodiments, outer surfaces 400_OS of the molding layer 400 and the outer surfaces 100_OS of the lower insulating layer 100 may be aligned (e.g., coplanar) in the vertical direction (Z direction). The outer surfaces 400_OS of the molding layer 400 may be spaced apart from the first semiconductor chip 200. For example, the first semiconductor chip 200 may be buried in the molding layer 400. For example, when the recess grooves 100_R of the lower insulating layer 100 overlap the outer surfaces 100_OS of the lower insulating layer 100 in the vertical direction (Z direction), one of the side surfaces of each of the protrusions 400_P of the molding layer 400 may be exposed to the outside of the semiconductor package 1000 and the other may be in contact with the inner surfaces 100_IS of the recess grooves 100_R of the lower insulating layer 100.

In one or more embodiments, the molding layer 400 may include an epoxy resin or a polyimide resin. The molding layer 400 may include, for example, an epoxy molding compound (EMC).

A contact area between the molding layer 400 and the lower insulating layer 100 may be relatively increased by the recess grooves 100_R of the lower insulating layer 100 and the protrusions 400_P of the molding layer 400. Accordingly, a phenomenon in which the molding layer 400 and the lower insulating layer 100 are peeled off may be suppressed.

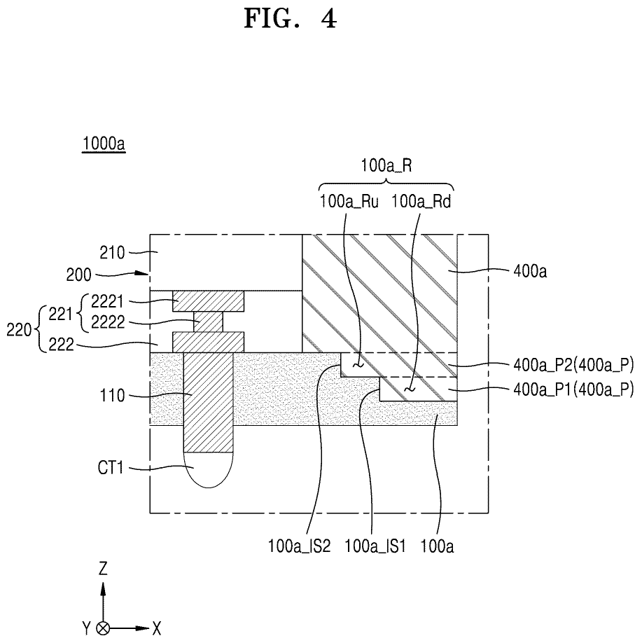

FIG. 4 is an enlarged view schematically illustrating a partially enlarged portion of the semiconductor package 1000a according to embodiments. In particular, FIG. 4 is an enlarged view of a portion of a lower insulating layer 100a in another embodiment of the semiconductor package 1000 of FIG. 3.

Most of components constituting the semiconductor package 1000a described below and the materials constituting the components may be substantially the same as or similar to those described above with reference to FIG. 3. Therefore, for convenience of explanation, differences between the semiconductor package 1000a of FIG. 4 and the semiconductor package 1000 of FIG. 3 are mainly described.

Referring to FIG. 4 together with FIG. 2, the lower insulating layer 100a may include recess grooves 100a_R. Portions of the lower insulating layer 100a that defines the recess grooves 100a_R may have a step shape. For example, portions of the lower insulating layer 100a defining the recess grooves 100a_R may have a step shape in which a width of the lower insulating layer 100a increases as a distance from the top surface of the lower insulating layer 100a increases.

For example, each of the recess grooves 100a_R of the lower insulating layer 100a may include an upper groove 100a_Ru and a lower groove 100a_Rd. The lower groove 100a_Rd may be positioned under the upper groove 100a_Ru, and may overlap with the upper groove 100a_Ru in the vertical direction (Z direction). For example, a width of a portion of the lower insulating layer where the lower groove 100a_Rd is located may be greater than a width of a portion of the lower insulating layer where the upper groove 100a_Ru is located. In FIG. 4, it is illustrated that the recess grooves 100a_R is formed in two stages, but the recess grooves 100a_R may be formed in three or more stages.

Protrusions 400a_P of the molding layer 400a may be located in the recess grooves 100a_R of the lower insulating layer 100a. Each of the protrusions 400a_P may include an upper protrusion 400a_P2 and a lower protrusion 400a_P1. The lower protrusion 400a_P1 may protrude downward from a bottom surface of the upper protrusion 400a_P2. The upper protrusion 400a_P2 may be a portion of the protrusions 400a_P located in the upper groove of the lower insulating layer 100a, and the lower protrusion 400a_P1 may be a portion of the protrusions 400a_P located in the lower groove 100a_Rd of the lower insulating layer 100a. For example, the upper protrusion 400a_P2 may be in contact with an inner surface 100a_IS2 of the upper groove 100a_Ru, and the lower protrusion 400a_P1 may be in contact with an inner surface 100a_IS1 of the lower groove 100a_Rd. An area of the lower protrusion 400a_P1 may be smaller than an area of the upper protrusion 400a_P2. For example, a shape of each of the protrusions 400a_P may correspond to (e.g., be the same as) a shape of each of the recess grooves 100a_R.

Since a portion of the lower insulating layer 100a is manufactured in a step shape, a contact area between the lower insulating layer 100a and the molding layer 400a may be increased. Accordingly, a phenomenon in which the molding layer 400a and the lower insulating layer 100a are peeled off may be suppressed.

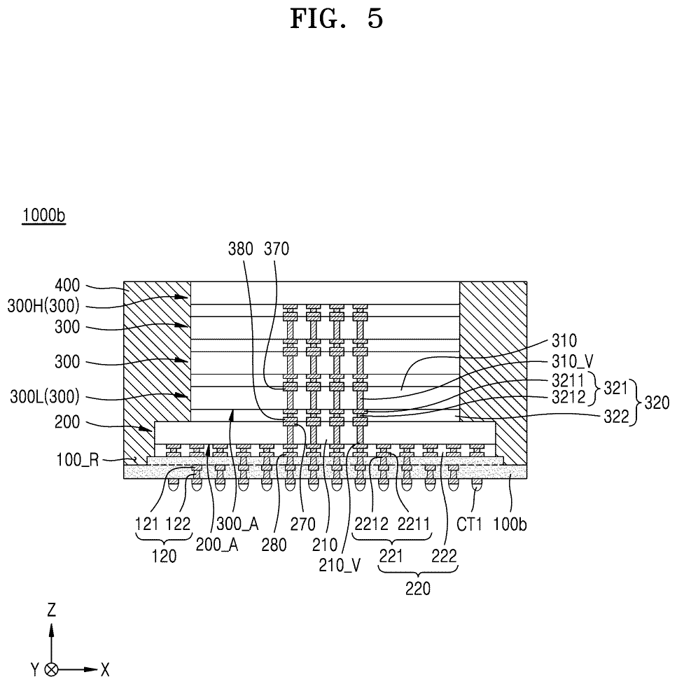

FIG. 5 is a cross-sectional view schematically illustrating a semiconductor package 1000b according to one or more embodiments.

Most of components constituting the semiconductor package 1000b described below and the materials constituting the components may be substantially the same as or similar to those described above with reference to FIG. 2. Therefore, for convenience of explanation, differences between the semiconductor package 1000b of FIG. 5 and the semiconductor package 1000 of FIG. 2 are mainly described.

Referring to FIG. 5, a semiconductor package 1000b may further include a redistribution pattern 120. The redistribution pattern 120 may electrically connect a plurality of first lower pads 280 of the first semiconductor chip 200 to the outside of the first semiconductor chip 200.

For example, a lower insulating layer 100b may have a multilayer structure in which the redistribution pattern 120 is arranged in each layer. In this case, the lower insulating layer 100b may be referred to as a redistribution insulating layer. For example, in the semiconductor package 1000b, a redistribution pattern 120 may be positioned inside the lower insulating layer 100b instead of the conductive pillars 110 of FIG. 2. The lower insulating layer 100b may include an insulating material such as, for example, a photo imageable dielectric (PID) resin or silicon oxide. In one or more embodiments, the lower insulating layer 100b may further include an inorganic filler.

The redistribution pattern 120 may include a redistribution line 121 extending in the horizontal direction and a redistribution via 122 extending from the redistribution line 121 in the vertical direction (Z direction). The redistribution line 121 may be arranged inside at least one from among the top surface, the bottom surface, and a portion therebetween of the lower insulating layer 100b. The redistribution via 122 may penetrate the lower insulating layer 100b to be connected to a portion of the redistribution line 121.

The redistribution pattern 120 may include a conductive material such as, for example, copper (Cu), aluminum (Al), silver (Ag), tin (Sn), gold (Au), nickel (Ni), lead (Pb), titanium (Ti), or alloys thereof.

In one or more embodiments, as the redistribution via 122 approaches the first semiconductor chip 200, a width of the redistribution via 122 in the first horizontal direction (X direction) and/or a width in the second horizontal direction (Y direction) may gradually decrease. That is, a horizontal area of the redistribution via 122 may decrease toward the first semiconductor chip 200.

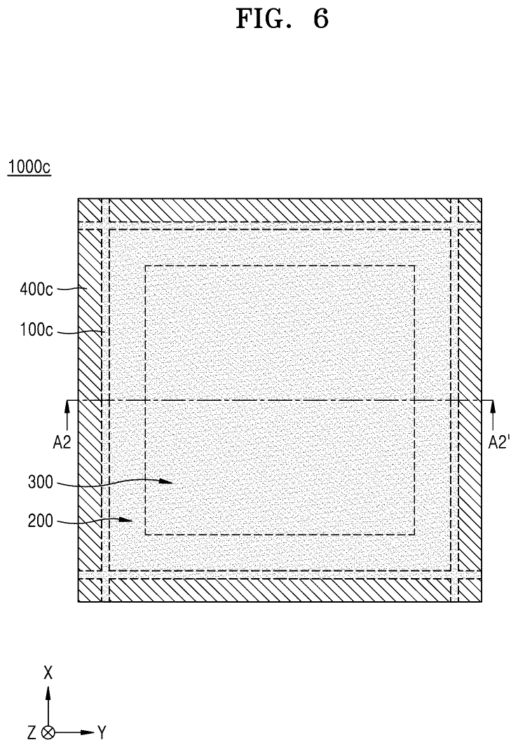

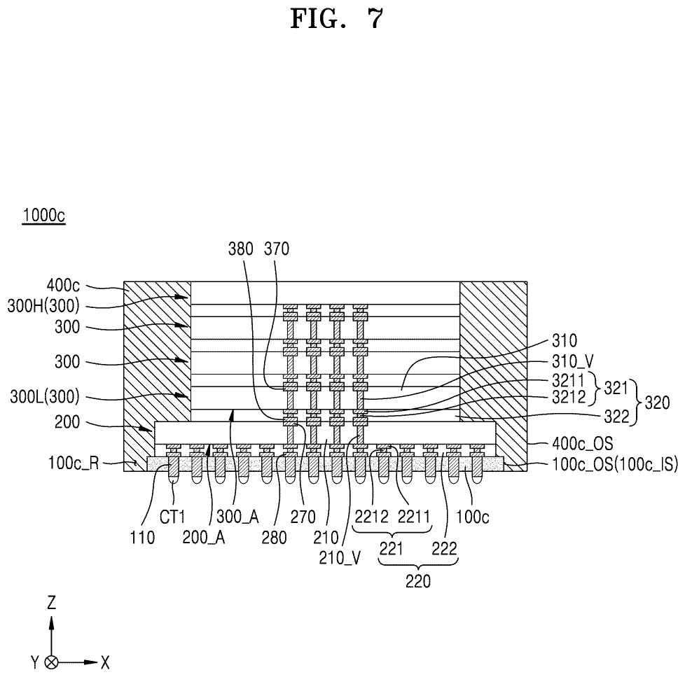

FIG. 6 is a bottom view schematically illustrating a semiconductor package 1000c according to one or more embodiments. FIG. 7 is a cross-sectional view schematically illustrating the semiconductor package 1000c of FIG. 6 taken along a line A2-A2′ of FIG. 6.

Most of components constituting the semiconductor package 1000c described below and the materials constituting the components may be substantially the same as or similar to those described above with reference to FIG. 2. Therefore, for convenience of explanation, differences between the semiconductor package 1000c of FIG. 7 and the semiconductor package 1000 of FIG. 2 are mainly described.

Referring to FIGS. 6 and 7, a semiconductor package 1000c may include a lower insulating layer 100c, the first semiconductor chip 200, the second semiconductor chip 300, and a molding layer 400c.

The lower insulating layer 100c may include recess grooves 100c_R. The recess grooves 100c_R may extend from a top surface to a bottom surface of the lower insulating layer 100c. That is, the recess grooves 100c_R may completely penetrate the lower insulating layer 100c. For example, if the recess grooves 100c_R are located on the respective sides of the top surface of the lower insulating layer 100c, a portion of the outer surface 100c_OS of the lower insulating layer 100c may be the inner surface 100c_IS of each of the recess grooves 100c_R.

In one or more embodiments, an outer surface of a portion of the molding layer 400c located in the recess grooves 100c_R may be spaced apart from the outer surface 100c_OS of the lower insulating layer 100c. For example, a bottom surface of a portion of the molding layer 400c located inside the recess grooves 100c_R may be coplanar with a bottom surface of the lower insulating layer 100c.

Each of the recess grooves 100c_R and the alignment grooves 100_AK (see FIG. 1) of the lower insulating layer 100c may completely penetrate the lower insulating layer 100c. Accordingly, a bottom surface of a portion of the molding layer 400c located in the recess grooves 100c_R or alignment grooves 100_AK (see FIG. 1) may be exposed to the outside. As shown in FIG. 6, a portion of the molding layer 400c may be exposed to the outside.

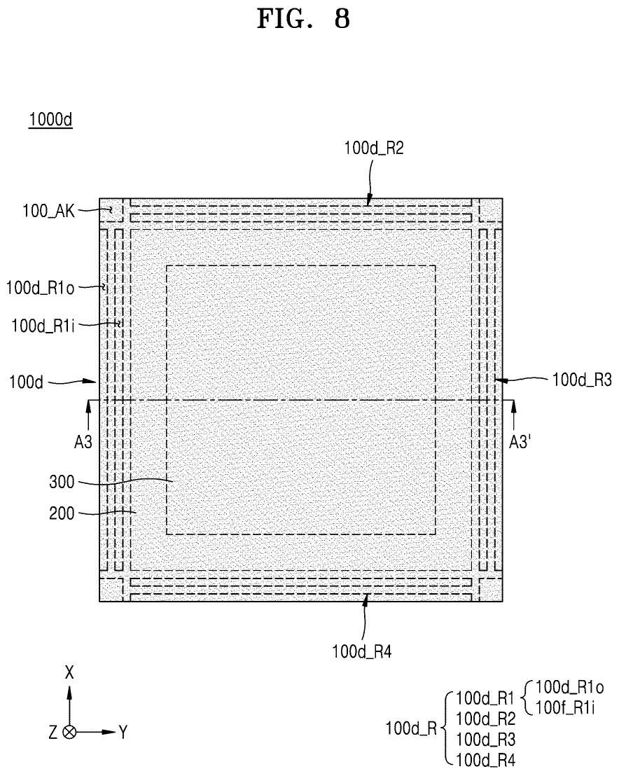

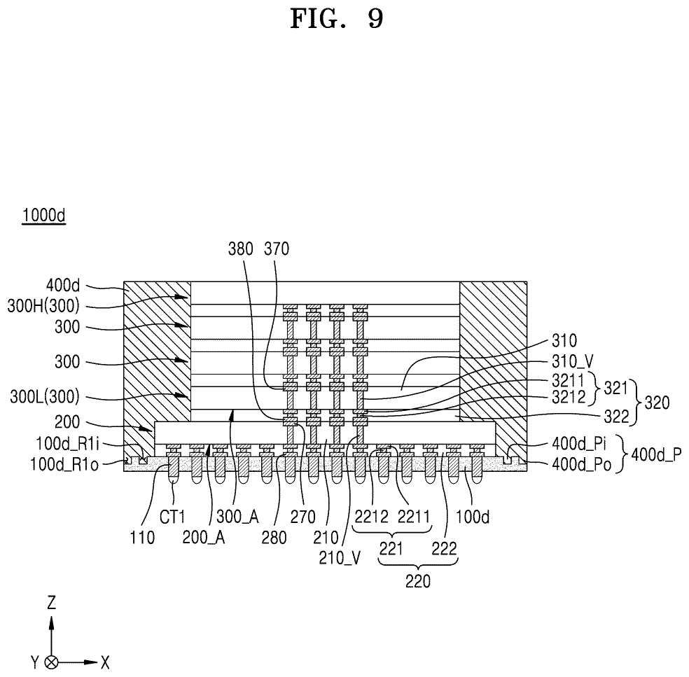

FIG. 8 is a bottom view schematically illustrating a semiconductor package 1000d according to one or more embodiments. FIG. 9 is a cross-sectional view schematically illustrating a semiconductor package 1000d of FIG. 8 taken along a line A3-A3′ of FIG. 8.

Most of components constituting the semiconductor package 1000d described below and the materials constituting the components may be substantially the same as or similar to those described above with reference to FIG. 2. Therefore, for convenience of explanation, differences between the semiconductor package 1000d of FIG. 9 and the semiconductor package 1000 of FIG. 2 are mainly described.

Referring to FIGS. 8 and 9, a semiconductor package 1000d may include a lower insulating layer 100d, the first semiconductor chip 200, the second semiconductor chip 300, and a molding layer 400d.

The lower insulating layer 100d may be positioned below the first semiconductor chip 200 and may have an area larger than an area of the first semiconductor chip 200. The lower insulating layer 100d may include recess grooves 100d_R. Each of the recess grooves 100d_R may extend along the respective sides of the top surface of the lower insulating layer 100d. For example, the recess grooves 100d_R may include a first recess groove 100d_R1, a second recess groove 100d_R2, a third recess groove 100d_R3, and a fourth recess groove 100d_R4.

Each of the recess grooves 100d_R may include an inner recess groove and an outer recess groove. For convenience of description, the first inner recess groove 100d_R1i and the first outer recess groove 100d_R1o are described with respect to the first recess groove 100d_R1. The first inner recess groove 100d_R1i and the first outer recess groove 100d_R1o may have the same extension direction as each other. The first inner recess groove 100d_R1i and the first outer recess groove 100d_R1o may be spaced apart from each other in the horizontal direction. The first inner recess groove 100d_R1i and the first outer recess groove 100d_R1o may be spaced apart from each other in a direction perpendicular to the extending direction of the first inner recess groove 100d_R1i.

A spacing distance between the first inner recess groove 100d_R1i and the first semiconductor chip 200 may be less than a spacing distance between the first outer recess groove 100d_R1o and the first semiconductor chip 200. The first inner recess groove 100d_R1i may be closer than the first outer recess groove 100d_R1o to the center of the top surface of the lower insulating layer 100d.

In one or more embodiments, the first outer recess groove 100d_R1o may be aligned (e.g., coplanar) with the first side surface 100_S1 (refer to FIG. 1) of the lower insulating layer 100d in the vertical direction (Z direction). The first inner recess groove 100d_R1i may be spaced apart from the first side surface 100_S1 of the lower insulating layer 100d.

In one or more embodiments, a shape of the first inner recess groove 100d_R1i and a shape of the first outer recess groove 100d_R1o may be independent. For example, the shape of the first inner recess groove 100d_R1i and the shape of the first outer recess groove 100d_R1o may be different from each other.

The molding layer 400d may include protrusions 400d_P. Each of the protrusions 400d_P may include an outer protrusion 400d_Po and an inner protrusion 400d_Pi. The outer protrusion 400d_Po and the inner protrusion 400d_Pi may be spaced apart from each other in the horizontal direction. A spacing distance between the outer protrusion 400d_Po and the first semiconductor chip 200 may be greater than a spacing distance between the inner protrusion 400d_Pi and the first semiconductor chip 200.

For example, a portion of the outer protrusion 400d_Po may be located in the first outer recess groove 100d_R1o, and a portion of the inner protrusion 400d_Pi may be located in the first inner recess groove 100d_R1i. One side surface of the outer protrusion 400d_Po may be exposed to the outside of the semiconductor package 1000d. All side surfaces of the inner protrusion 400d_Pi may be positioned inside the lower insulating layer 100d.

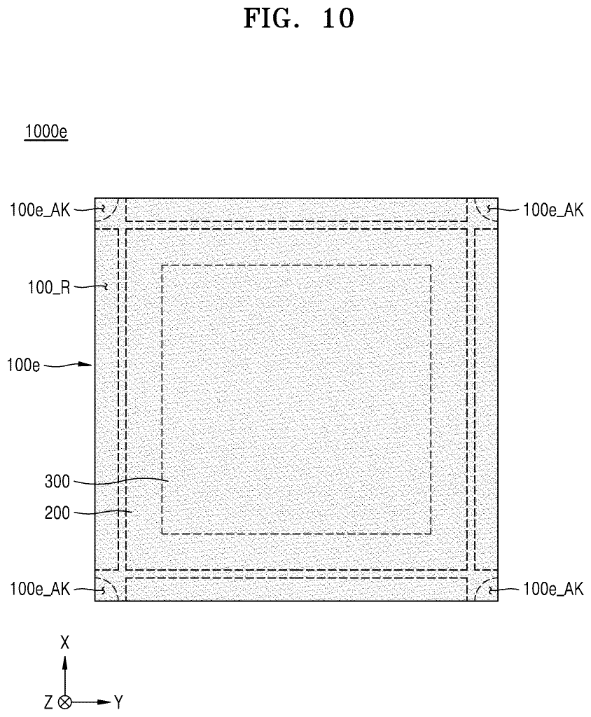

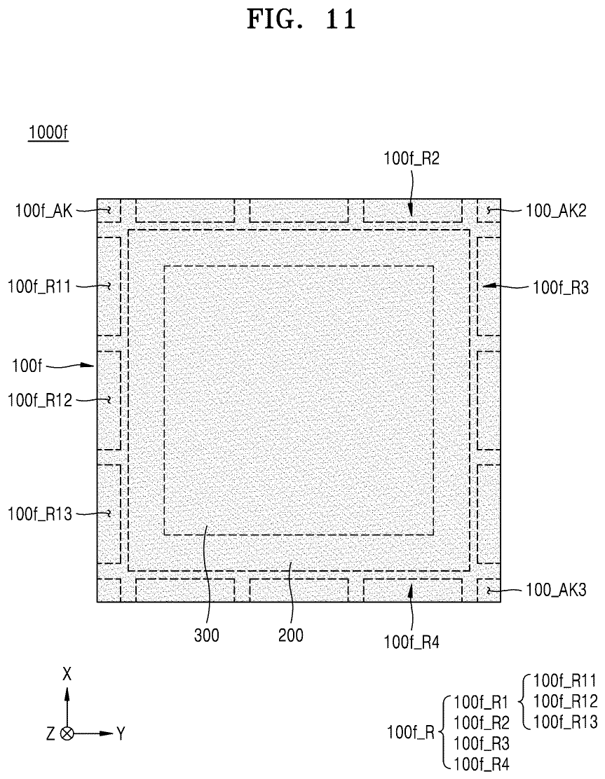

FIG. 10 is a bottom view schematically illustrating a semiconductor package 1000e according to one or more embodiments. FIG. 11 is a bottom view schematically illustrating a semiconductor package 1000f according to one or more embodiments.

Most of components constituting the semiconductor packages 1000e and 1000f described below and the materials constituting the components may be substantially the same as or similar to those described above with reference to FIG. 2. Therefore, for convenience of explanation, differences between each of the semiconductor packages 1000e and 1000f of FIGS. 10 and 11 and the semiconductor package 1000 of FIG. 2 are mainly described.

Referring to FIG. 10, the lower insulating layer 100e of the semiconductor package 1000e may include recess grooves 100_R and alignment grooves 100e_AK. For example, shapes of the recess grooves 100_R may be different from shapes of the alignment grooves 100e_AK. For example, each of the alignment grooves 100e_AK may have a quarter-circle shape, and each of the recess grooves 100_R may have a rectangular shape. For example, a cross section of each of the alignment grooves 100e_AK may be formed to have a polygonal shape or a specific shape, and a cross section of each of the recess grooves 100_R may be formed to have a different shape from the shape of each of the alignment grooves 100e_AK.

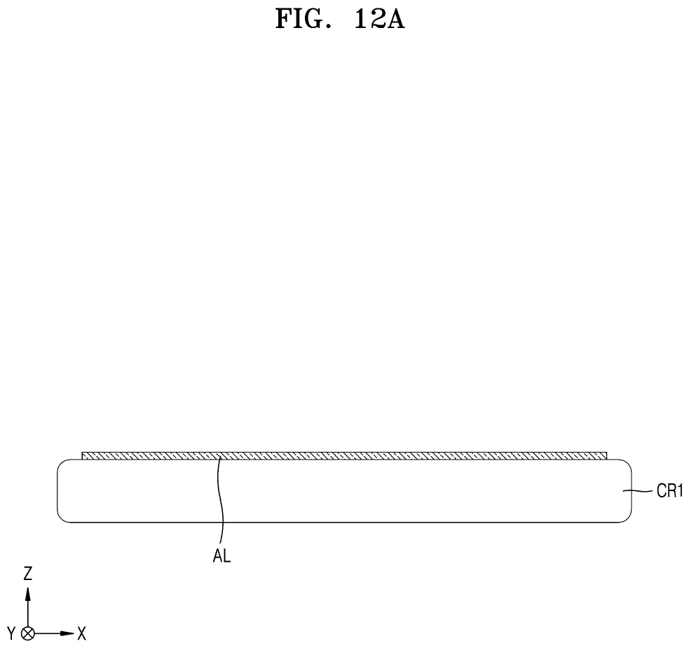

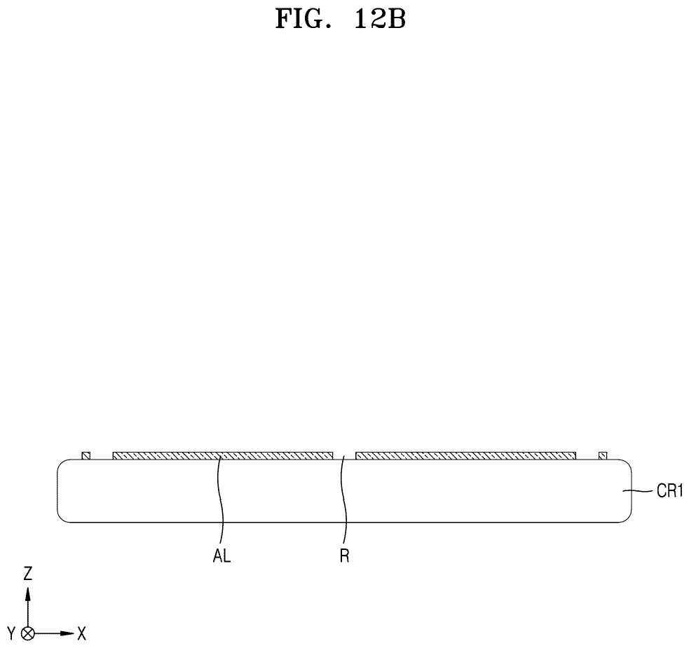

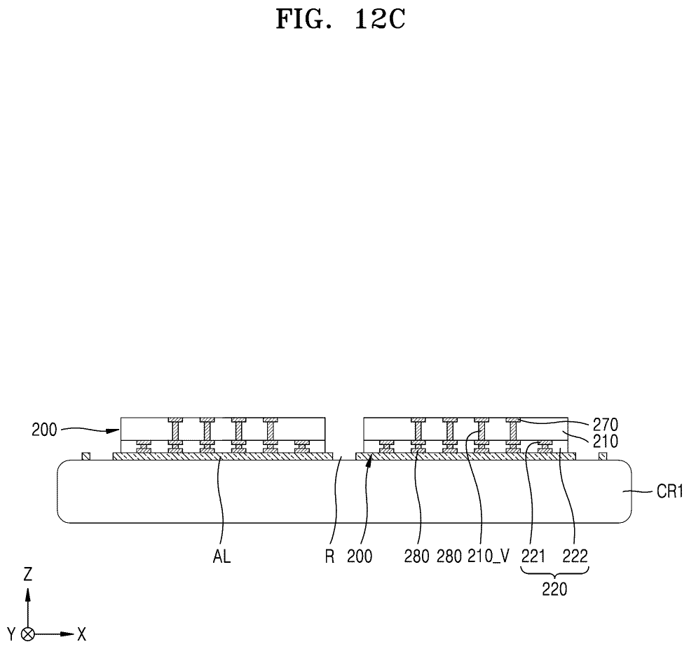

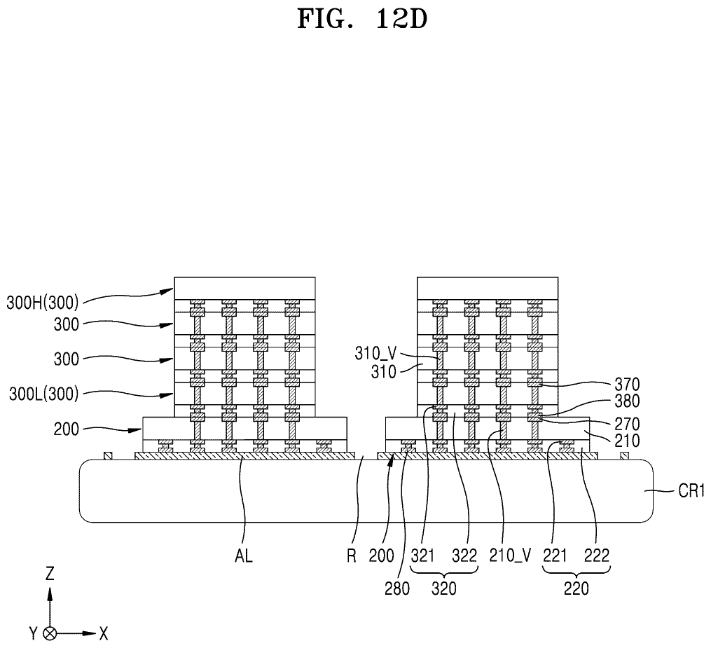

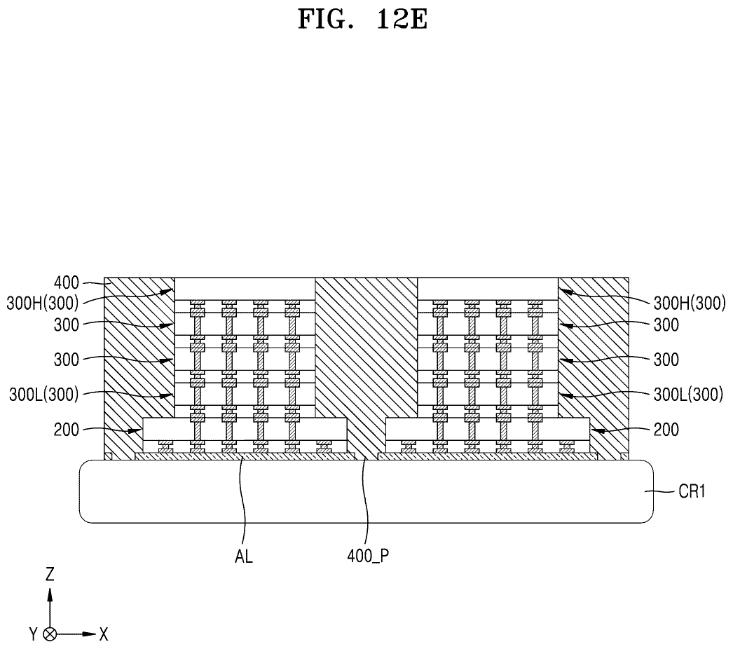

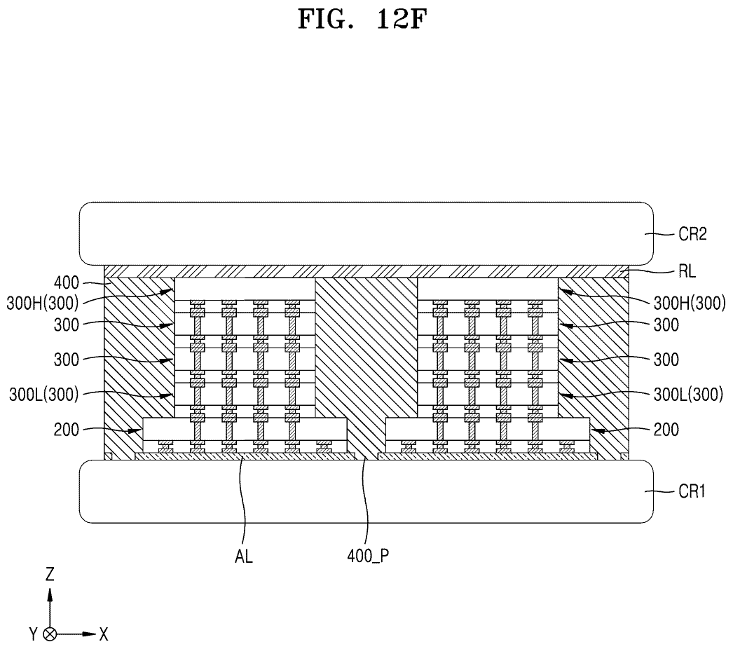

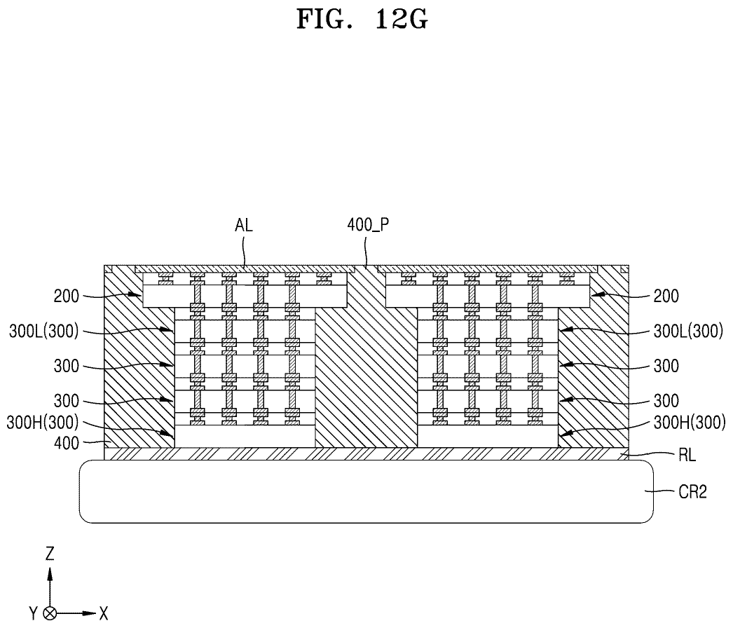

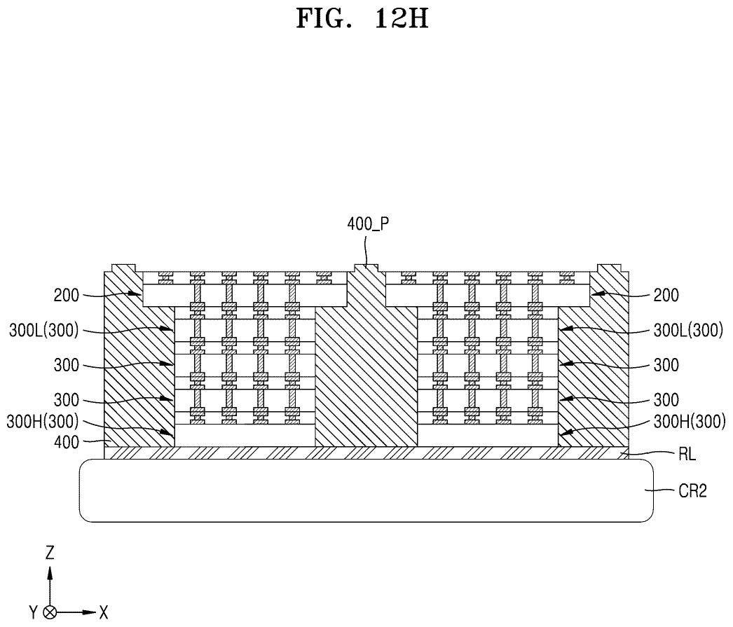

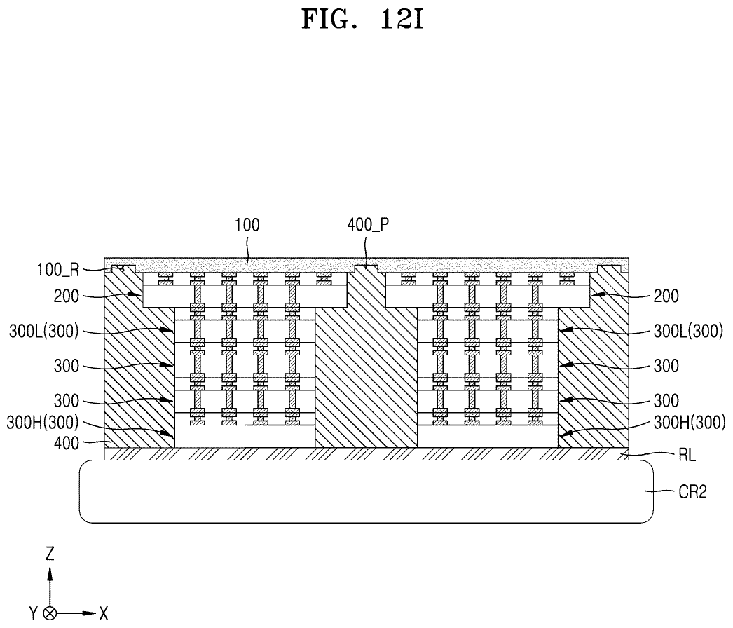

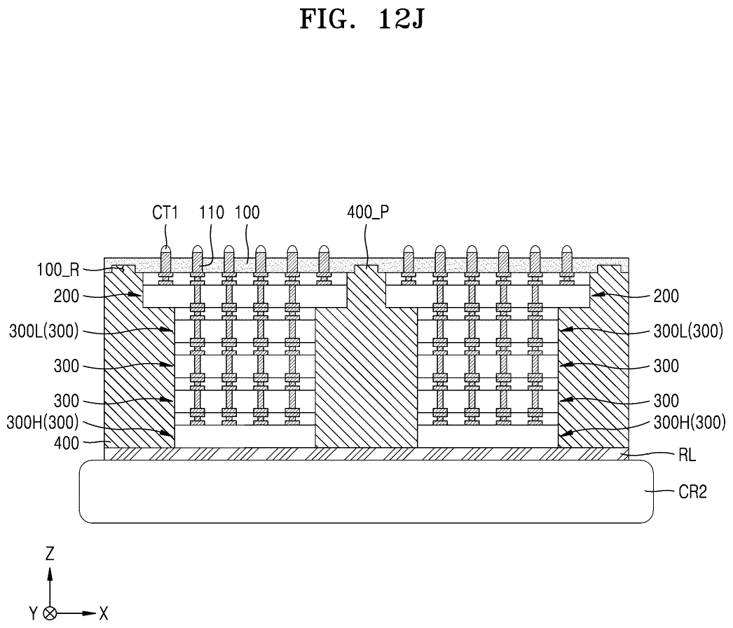

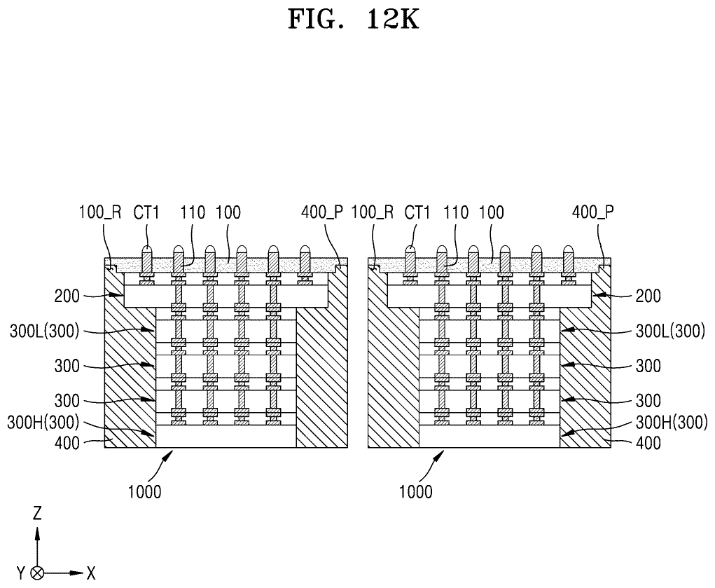

For example, the alignment grooves 100e_AK may be used when adjusting the position of the first semiconductor chip 200 in the process of mounting the first semiconductor chip 200 on a carrier substrate (e.g. a first carrier substrate CR1 of FIG. 12A). The recess grooves 100_R may prevent the first semiconductor chip 200 from moving due to thermal expansion of the molding layer 400 (see FIG. 2) when forming the molding layer 400 (see FIG. 2). When the position of the first semiconductor chip 200 is adjusted based on the alignment grooves 100e_AK, shapes of the alignment grooves 100e_AK and the recess grooves 100_R may be different from each other to clearly distinguish the alignment grooves 100e_AK from the recess grooves 100_R.

Referring to FIG. 11, the lower insulating layer 100f of the semiconductor package 1000f may include recess grooves 100f_R. The recess grooves 100f_R may include first recess grooves 100f_R1, second recess grooves 100f_R2, third recess grooves 100f_R3, and fourth recess grooves 100f_R4. For example, referring to FIG. 11 together with FIG. 1, the first recess grooves 100f_R1 may be recess grooves extending along the first side surface 100_S1 of the lower insulating layer 100f. The second recess grooves 100f_R2 may be recess grooves extending along the second side surface 100_S2 of the lower insulating layer 100f. The third recess grooves 100f_R3 may be recess grooves extending along the third side surface 100_S3 of the lower insulating layer 100f. The fourth recess grooves 100f_R4 may be recess grooves extending along the fourth side surface 100_S4 of the lower insulating layer 100f.

For example, there may be a plurality of recess grooves extending along one side surface of the lower insulating layer 100f. For example, the number of recess grooves overlapping one side surface of the lower insulating layer 100f in the vertical direction (Z direction) may be two or more. For example, the number of recess grooves positioned between two adjacent alignment grooves among the alignment grooves 100f_AK may be two or more.

For convenience of description, the first recess grooves 100f_R1 are described as a reference. The first recess grooves 100f_R1 may extend in the same direction as each other. For example, with reference to FIG. 11, each of the first recess grooves 100f_R1 may extend in the first horizontal direction (X direction). The first recess grooves 100f_R1 may be spaced apart from each other. The first recess grooves 100f_R1 may be spaced apart from each other in the first horizontal direction (X direction). For example, the first recess grooves 100f_R1 may include a first groove 100f_R11, a second groove 100f_R12, and a third groove 100f_R13. The first groove 100f_R11 may be spaced apart from the second groove 100f_R12 and the third groove 100f_R13 in the horizontal direction. The second groove 100f_R12 may be positioned between the first groove 100f_R11 and the third groove 100f_R13. For example, the shape of each of the first groove 100f_R11, the second groove 100f_R12, and the third groove 100f_R13 may be different from the shape of each of the alignment grooves 100_AK (see FIG. 1). For example, a size of an area of each of the first groove 100f_R11, the second groove 100f_R12, and the third groove 100f_R13 may be greater than a size of an area of each of the alignment grooves 100f_AK.

FIGS. 12A to 12K are schematic diagrams illustrating a method of manufacturing a semiconductor package 1000 according to one or more embodiments. FIGS. 12A to 12K are diagrams schematically illustrating a manufacturing process of the semiconductor package 1000 of FIG. 2.

Referring to FIGS. 12A to 12K, a method of manufacturing the semiconductor package 1000 may include: forming an adhesive layer AL on a first carrier substrate CR1; forming preliminary recess grooves R in the adhesive layer AL; mounting the first semiconductor chip 200 on the adhesive layer AL; mounting one or more second semiconductor chips 300 on the first semiconductor chip 200; forming the molding layer 400 on the adhesive layer AL to surround the first semiconductor chip 200 and the one or more second semiconductor chips 300; removing the adhesive layer AL and forming the lower insulating layer 100; and forming the conductive pillars 110 to penetrate the lower insulating layer 100.

Referring to FIGS. 12A and 12B, after the adhesive layer AL is formed on the top surface of the first carrier substrate CR1, the preliminary recess grooves R penetrating at least a portion of the adhesive layer AL may be formed. In one or more embodiments, the adhesive layer AL may be an adhesive film such as a die attached film (DAF).

In one or more embodiments, the preliminary recess grooves R may be at least partially recessed from the top surface of the adhesive layer AL to the inside of the adhesive layer AL. For example, the preliminary recess grooves R may completely penetrate the adhesive layer AL, or may only partially penetrate the adhesive layer AL. The preliminary recess grooves R may be substantially the same as the alignment grooves 100_AK (refer to FIG. 1) and the recess grooves 100_R of the lower insulating layer 100 to be formed later. In one or more embodiments, the recess grooves 100_R may have shapes of the recess grooves 100_R, 100a_R, 100c_R, 100d_R, and 100f_R described above according to a method of forming the preliminary recess grooves R.

For example, in the operation of mounting the first semiconductor chip 200 on the adhesive layer AL, some of the preliminary recess grooves R may be used to adjust the position of the first semiconductor chip 200, and some others of the preliminary recess grooves R may be used to reduce the stress generated in the molding layer 400. In one or more embodiments, the preliminary recess grooves R may be formed through a laser process.

Referring to FIG. 12C, the first semiconductor chip 200 may be mounted on the adhesive layer AL. For example, the first semiconductor chip 200 may be mounted on the adhesive layer AL so that a first wiring structure 220 of the first semiconductor chip 200 faces the adhesive layer AL. For example, a plurality of first semiconductor chips 200 may be mounted on one first carrier substrate CR1 to be spaced apart from each other in the horizontal direction. For example, in order to position a plurality of first semiconductor chips 200 at preset positions, some of the preliminary recess grooves R may be used. In one or more embodiments, a plurality of first semiconductor chips 200 may be spaced apart from the preliminary recess grooves R in the horizontal direction.

Referring to FIG. 12D, a plurality of second semiconductor chips 300 may be mounted on each of the first semiconductor chips 200. For example, a width of each of the plurality of second semiconductor chips 300 may be less than a width of the first semiconductor chip 200 on which the plurality of second semiconductor chips 300 are mounted. Side surfaces of the plurality of second semiconductor chips 300 may overlap the top surface of the first semiconductor chip 200 in the vertical direction (Z direction).

For example, the plurality of second semiconductor chips 300 may be electrically connected to a plurality of first through electrodes 210_V of the first semiconductor chip 200. In one or more embodiments, a plurality of second lower pads 380 of a lowermost second semiconductor chip 300L may be integrated with a plurality of first upper pads 270 of the first semiconductor chip 200 by diffusion bonding. For example, the plurality of second semiconductor chips 300 and the first semiconductor chip 200 may be combined through hybrid bonding between two adjacent ones of the second semiconductor chips 300 among the plurality of second semiconductor chips 300 and between the lowermost second semiconductor chip 300L and the first semiconductor chip 200.

Referring to FIG. 12E, a molding layer 400 may be formed on the adhesive layer AL to cover the first semiconductor chips 200 and the plurality of second semiconductor chips 300. The molding layer 400 may fill the inside of the preliminary recess grooves R. For example, portions of the molding layer 400 located inside the preliminary recess grooves R may be referred to as protrusions 400_P of the molding layer 400. The molding layer 400 may be in contact with the side surfaces of the first semiconductor chips 200, the side surfaces of each of the plurality of second semiconductor chips 300, and a portion of the top surface of the adhesive layer AL. The protrusions 400_P of the molding layer 400 may be in contact with inner surfaces of the preliminary recess grooves R.

Thereafter, a portion of the molding layer 400 may be removed until the top surface of the uppermost second semiconductor chip 300H is exposed. Accordingly, the top surface of the molding layer 400 and the top surface of the uppermost second semiconductor chip 300H may be coplanar.

In the process of forming the molding layer 400, the protrusions 400_P of the molding layer 400 may fill the preliminary recess grooves R, so that stress generated in the molding layer 400 may be reduced. For example, in a comparative embodiment, due to the difference in the thermal expansion coefficients between the molding layer 400 and the adhesive layer AL, the position of the first semiconductor chip 200 located in the molding layer 400 may be moved. According to embodiments of the disclosure, due to the protrusions 400_P of the molding layer 400, the stress generated in the molding layer 400 is reduced, so that the movement of the first semiconductor chip 200 may be suppressed.

Referring to FIGS. 12F and 12G, the resultant of FIG. 12E may be transferred to a second carrier substrate CR2. For example, the second carrier substrate CR2 including a release layer RL may be attached to the top surface of the resultant of FIG. 12E. After attaching the second carrier substrate CR2 onto the molding layer 400, the first carrier substrate CR1 may be removed.

For example, while the adhesive layer AL remains under the first semiconductor chip 200 and the molding layer 400, the adhesive layer AL may be separated from the first carrier substrate CR1. For example, in the process of removing the first carrier substrate CR1, the resultant of FIG. 12f may be reversed so that the adhesive layer AL is located at the top thereof and the second carrier substrate CR2 is located at the bottom thereof.

Referring to FIGS. 12H and 12I, a lower insulating layer 100 may be formed. From the resultant of FIG. 12H, the adhesive layer AL may be removed to expose the top surface (relative to FIGS. 12H and 121) of the molding layer 400 and the top surfaces (relative to FIGS. 12H and 121) of the first semiconductor chips 200 to the outside. Thereafter, the lower insulating layer 100 may be formed on the top surface (relative to FIGS. 12H and 121) of the molding layer 400 and the top surface (relative to FIGS. 12H and 121) of the first semiconductor chip 200. The lower insulating layer 100 may surround the protrusions 400_P of the molding layer 400. The portions of the lower insulating layer 100, which are recessed inward to surround the protrusions 400_P of the molding layer 400 may be referred to as recess grooves 100_R or alignment grooves 100_AK (see FIG. 1). For example, the recess grooves 100_R and alignment grooves 100_AK (see FIG. 1) of the lower insulating layer 100 may have substantially the same shapes as the preliminary recess grooves R described above.

In one or more embodiments, when some portions of the lower insulating layer 100 are removed so that the top surfaces (relative to FIGS. 12H and 121) of the protrusions 400_P of the molding layer 400 are exposed, the recess grooves 100_R and alignment grooves 100_AK (see FIG. 1) may completely penetrate the lower insulating layer 100 like as in the semiconductor package 1000c of FIG. 6.

Referring to FIG. 12J, conductive pillars 110 penetrating the lower insulating layer 100 may be formed. Thereafter, external connection terminals CT1 may be formed on the conductive pillars 110, respectively. In one or more embodiments, the external connection terminals CT1 may be attached onto the conductive pillars 110 after cutting the lower insulating layer 100 and the molding layer 400.

A plurality of trenches extending from a top surface to a bottom surface of the lower insulating layer 100 may be formed. The plurality of trenches may be located above (relative to FIG. 12J) the first semiconductor chip 200. For example, the plurality of trenches may be located above (relative to FIG. 12J) the plurality of first lower pads 280 of the first semiconductor chip 200. The plurality of first lower pads 280 of the first semiconductor chip 200 may be exposed to the outside through the plurality of trenches.

For example, the plurality of trenches may be formed in portions of the lower insulating layer 100 in contact with the first semiconductor chip 200, and may not be formed in portions of the lower insulating layer 100 in contact with the molding layer 400.

Thereafter, the inside of each of the plurality of trenches may be filled with a conductive material to form the conductive pillars 110. For example, a conductive material may be filled inside the plurality of trenches through an electroplating process.

In one or more embodiments, in the process of forming the conductive pillars 110, the conductive pillars 110 may protrude to the outside of the lower insulating layer 100. For example, since the length of each of the conductive pillars 110 may be greater than the thickness of the lower insulating layer 100, the conductive pillars 110 may protrude to the outside of the lower insulating layer 100.

Referring to FIG. 12K, the resultant of FIG. 12J may be cut to be a plurality of semiconductor packages 1000. For example, the resultant of FIG. 12J may be cut along the recess grooves 100_R. For example, the resultant product of FIG. 12J may be cut so that the molding layer 400 remains on the sides of the first semiconductor chip 200 and the plurality of second semiconductor chips 300. For example, the first semiconductor chip 200 may be located inside the molding layer 400 and may not be exposed to the outside.

While non-limiting example embodiments have been particularly shown and described with reference to the accompanying drawings, it will be understood that various changes in form and details may be made therein without departing from the spirit and scope of the disclosure.

What is claimed is:

1. A semiconductor package comprising:
a lower insulating layer comprising recess grooves recessed into the lower insulating layer from a top surface of the lower insulating layer;
a first semiconductor chip on the lower insulating layer in a first vertical direction, and spaced apart from the recess grooves in at least one horizontal direction, the first semiconductor chip comprising a first through electrode;
a second semiconductor chip on the first semiconductor chip in the first vertical direction; and
a molding layer in contact with the top surface of the lower insulating layer, a side surface of the first semiconductor chip, and a side surface of the second semiconductor chip,
wherein, in a plan view of the semiconductor package, a size of an area of the lower insulating layer is greater than a size of an area of the first semiconductor chip, and
wherein portions of the molding layer are in the recess grooves of the lower insulating layer.

2. The semiconductor package of claim 1, further comprising a conductive pillar under the first semiconductor chip in a second vertical direction, opposite to the first vertical direction, and electrically connected to the first semiconductor chip,
wherein the conductive pillar penetrates the lower insulating layer, and
wherein a portion of the conductive pillar protrudes from a bottom surface of the lower insulating layer.

3. The semiconductor package of claim 1, further comprising a redistribution pattern in the lower insulating layer, the redistribution pattern comprising a redistribution line extending in the at least one horizontal direction and a redistribution via vertically extending from the redistribution line.

4. The semiconductor package of claim 1, wherein the recess grooves of the lower insulating layer are recessed inward from a side surface of the lower insulating layer.

5. The semiconductor package of claim 4, wherein each of the recess grooves of the lower insulating layer extends along one of sides of the top surface of the lower insulating layer.

6. The semiconductor package of claim 1, wherein a portion of the lower insulating layer defining the recess grooves of the lower insulating layer comprises a stepped shape in which a width of the lower insulating layer increases as a distance from the top surface of the lower insulating layer increases.

7. The semiconductor package of claim 1, wherein each of the recess grooves of the lower insulating layer includes an inner recess groove and an outer recess groove spaced apart from the inner recess groove, and
wherein a spacing distance between the inner recess groove and the first semiconductor chip is less than a spacing distance between the outer recess groove and the first semiconductor chip.

8. The semiconductor package of claim 7, wherein the outer recess groove of each of the recess grooves overlaps a side surface of the lower insulating layer in the first vertical direction.

9. The semiconductor package of claim 1, wherein the recess grooves of the lower insulating layer completely penetrate the lower insulating layer, and
wherein a bottom surface of a portion of the molding layer is coplanar with a bottom surface of the lower insulating layer.

10. The semiconductor package of claim 1, wherein the recess grooves include first recess grooves extending along a first side surface of the lower insulating layer, and
wherein the first recess grooves are spaced apart from each other in an extending direction of the first recess grooves.

11. The semiconductor package of claim 1, wherein the lower insulating layer further includes alignment grooves extending into the lower insulating layer from the top surface of the lower insulating layer,
wherein each of the alignment grooves has a shape that is different from a shape of each of the recess grooves, and
wherein a portion of the molding layer is in the alignment grooves.

12. The semiconductor package of claim 11, wherein the alignment grooves are at vertices of the top surface of the lower insulating layer, and
wherein the alignment grooves are spaced apart from the recess grooves.

13. The semiconductor package of claim 11, wherein, in the plan view of the semiconductor package, a size of an area of each of the alignment grooves is different from a size of an area of each of the recess grooves.

14. A semiconductor package comprising:
a lower insulating layer comprising recess grooves recessed into the lower insulating layer from a top surface of the lower insulating layer, and alignment grooves spaced apart from the recess grooves;
a first semiconductor chip on the lower insulating layer in a first vertical direction, and spaced apart from the recess grooves and the alignment grooves in at least one horizontal direction, the first semiconductor chip comprising a first through electrode;
a plurality of second semiconductor chips on the first semiconductor chip in the first vertical direction; and
a molding layer in contact with the top surface of the lower insulating layer, a side surface of the first semiconductor chip, and side surfaces of the plurality of second semiconductor chips,
wherein side surfaces of the first semiconductor chip overlap the top surface of the lower insulating layer in the first vertical direction,
wherein the molding layer comprises protrusions in contact with a side surface of each of the recess grooves of the lower insulating layer or in contact with a side surface of each of the alignment grooves of the lower insulating layer, and
wherein a shape of each of the recess grooves is different from a shape of each of the alignment grooves.

15. The semiconductor package of claim 14, wherein the lower insulating layer comprises a central region and an edge region surrounding the central region,
wherein the first semiconductor chip and the plurality of second semiconductor chips are on the central region of the lower insulating layer, and
wherein the protrusions of the molding layer are on the edge region of the lower insulating layer.

16. The semiconductor package of claim 14, wherein each of the recess grooves extends along a side of the top surface of the lower insulating layer, and
wherein each of the alignment grooves is at a vertex of the top surface of the lower insulating layer.

17. The semiconductor package of claim 14, wherein outer surfaces of the molding layer are coplanar with outer surfaces of the lower insulating layer, and
wherein the first semiconductor chip is inside the molding layer.

18. The semiconductor package of claim 14, wherein each of the protrusions of the molding layer includes an inner protrusion and an outer protrusion, and
wherein a spacing distance between the inner protrusion and the first semiconductor chip is less than a spacing distance between the outer protrusion and the first semiconductor chip.

19. A semiconductor package comprising:
a lower insulating layer comprising recess grooves recessed into the lower insulating layer from a top surface of the lower insulating layer, and alignment grooves spaced apart from the recess grooves;
a first semiconductor chip on the lower insulating layer in a first vertical direction, and spaced apart from the recess grooves and the alignment grooves in at least one horizontal direction, the first semiconductor chip comprising a first through electrode;
a conductive pillar that penetrates the lower insulating layer and is electrically connected to the first semiconductor chip;
an external connection terminal connected to the conductive pillar;
a plurality of second semiconductor chips on the first semiconductor chip; and
a molding layer in contact with the top surface of the lower insulating layer, a side surface of the first semiconductor chip, and side surfaces of the plurality of second semiconductor chips,
wherein side surfaces of the first semiconductor chip overlap the top surface of the lower insulating layer in the first vertical direction,
wherein side surfaces of each of the plurality of second semiconductor chips overlap a top surface of the first semiconductor chip in the first vertical direction,
wherein the molding layer comprises protrusions in contact with a side surface of each of the recess grooves of the lower insulating layer or in contact with a side surface of each of the alignment grooves of the lower insulating layer,
wherein an outer surface of the molding layer is coplanar with an outer surface of the lower insulating layer,
wherein the first semiconductor chip is inside the molding layer, and
wherein a shape of each of the recess grooves is different from a shape of each of the alignment grooves.

20. The semiconductor package of claim 19, wherein the lower insulating layer comprises a first side surface, a second side surface adjacent to the first side surface, a third side surface opposite the first side surface, and a fourth side surface opposite the second side surface,
wherein the recess grooves comprise a first recess groove extending along the first side surface of the lower insulating layer, a second recess groove extending along the second side surface of the lower insulating layer, a third recess groove extending along the third side surface of the lower insulating layer, and a fourth recess groove extending along the fourth side surface of the lower insulating layer, and
wherein the first recess groove overlaps the first side surface of the lower insulating layer in the first vertical direction, the second recess groove overlaps the second side surface of the lower insulating layer in the first vertical direction, the third recess groove overlaps the third side surface of the lower insulating layer in the first vertical direction, and the fourth recess groove overlaps the fourth side surface of the lower insulating layer in the first vertical direction.
